(19) United States
(12) Patent Application Publication
(10) Pub. No.: US 2011/0272729 A1
(43) Pub. Date: Nov. 10, 2011

(54) WAFER LEVEL LED INTERPOSER

(75) Inventors: Gu-Sung Kim, Gyeonggi-do (KR); Jae-June Kim, Gyeonggi-do (KR); Young-Mo Koo, Seoul (KR)

(73) Assignee: EPWORKS CO., LTD., Gyeonggi-do (KR)

(21) Appl. No.: 13/098,625

(22) Filed: May 2, 2011

(30) Foreign Application Priority Data
May 6, 2010 (KR) 10-2010-0042630

(51) Int. Cl. H01L 33/62

(52) U.S. Cl. 257/99; 438/26; 257/E33.066

(57) ABSTRACT

A wafer level LED interposer and its manufacturing method is provided. The wafer level LED interposer includes: a LED chip of which N-type electrode and p-type electrode are formed on the upper side; an interposer substrate formed with through vias at each position corresponding to the N-type electrode and the p-type electrode and bonded to the upper side of the LED chip, wherein the N-type electrode and p-type electrode are connected to each through via; a redistribution layer formed on the upper surface of the interposer substrate and electrically connected to the through vias; a solder resist layer coated on the upper surface of the interposer substrate for a part of the redistribution layer selectively to be opened; and an external connector formed at the position where the redistribution layer is opened.

### CROSS-REFERENCE TO RELATED APPLICATION

This application claims the benefit of priority to Korean Application No. 10-2010-0042630, filed May 6, 2010, the contents of which are incorporated herein by reference.

### BACKGROUND

1. Technical Field

The present invention relates to a wafer level LED interposer.

2. Description of the Related Art

The trend is heading to micro-miniaturization and weight reduction in semiconductor packages in response to demands for electronic devices with greater capabilities, higher productivities, multi-functionalities and smaller sizes. Particularly, a wafer level LED interposer (wafer level package: WLP), which processes at a wafer level where semiconductor chips such as LED chips are integrated, is being developed as a next generation semiconductor package technology. Since the wafer level LED interposer technology offers products with smaller and thinner size, manufacturing cost savings, and improved electrical performance, etc., it has been utilized a lot to develop optical image sensors such as CMOS image sensors and the like

### SUMMARY

The present invention provides a wafer level LED interposer which can increase efficiency of the light emitted from a LED chip and reduce manufacturing cost, and a method for manufacturing the same.

According to an aspect of the present invention, there is provided a wafer level LED interposer comprising: a LED chip of which n-type electrode and the p-type electrode are formed on the upper side; an interposer substrate formed with through vias at each position corresponding to the n-type electrode and the p-type electrode and bonded to the upper side of the LED chip, wherein the n-type electrode and the p-type electrode are connected to each through via; a redistribution layer formed on the upper surface of the interposer substrate and electrically connected to the through vias; a solder resist layer coated on the upper surface of the interposer substrate for a part of the redistribution layer selectively to be opened; and an external connector formed at the position where the redistribution layer is opened.

A thickness of the LED chip may be formed thinner than that of the interposer substrate.

The interposer substrate may be glass or silicon.

The redistribution layer may be formed of a conductive material including at least one chosen from Cr, Cu and Ni.

The external connector may include a solder ball to be attached to the position where the redistribution layer is opened.

The wafer level LED interposer may further include a bonding layer formed between the LED chip and the interposer substrate and bonding the LED chip and the interposer substrate.

The LED chip may include a sapphire substrate; and a nitride semiconductor structure laminated on the sapphire substrate in which the nitride semiconductor structure may include a p- and n-type semiconductor layer of a nitrogenous compound.

The wafer level LED interposer may further include a fluorescent material layer formed on the bottom surface of the LED chip; and a molding lens formed thereon to cover the fluorescent material layer.

According to another aspect of the present invention, there is provided a method for manufacturing a wafer level LED interposer comprising: forming a LED chip of which a n-type electrode and a p-type electrode are formed on the upper side; bonding an interposer substrate formed with through holes at each position corresponding to the n-type electrode and the p-type electrode to the upper side of the LED chip, wherein the n-type electrode and the p-type electrode are exposed by the through holes; forming through vias by filling inside the each through hole with a conductive material, wherein the n-type electrode and the p-type electrode are connected to each through via; forming a redistribution layer electrically connected to the through vias on the upper surface of the interposer substrate; coating a solder resist layer on the upper surface of the interposer substrate for a part of the redistribution layer selectively to be opened; and forming an external connector at the position where the redistribution layer is opened.

The bonding step may be performed by interposing a bonding layer between the LED chip and the interposer substrate.

The step of forming through vias and the step of forming a redistribution layer may be performed by the same process through electroless plating and electro plating method.

The interposer substrate may be glass or silicon.

The LED chip may include a sapphire substrate; and a nitride semiconductor structure laminated on the sapphire substrate in which the nitride semiconductor structure comprises a p- and n-type semiconductor layer of a nitrogenous compound.

The method for manufacturing a wafer level LED interposer may further include coating a fluorescent material layer on the bottom surface of the LED chip; and forming a molding lens thereon to cover the fluorescent material layer.

A wafer level LED interposer according to an embodiment of the present invention is able to increase efficiency of the light and reduce manufacturing cost.

### BRIEF DESCRIPTION OF THE DRAWINGS

FIG. 1 is a sectional view illustrating a wafer level LED interposer according to an embodiment of the present invention.

FIG. 2 illustrates light emitting from a wafer level LED interposer according to an embodiment of the present invention.

FIG. 3a to FIG. 3k illustrate each process for manufacturing a wafer level LED interposer according to an embodiment of the present invention.

FIG. 4a to FIG. 4d illustrate a method for forming through vias on an interposer substrate.

### DETAILED DESCRIPTION

While the present invention has been described with reference to particular embodiments, it is to be appreciated that various changes and modifications may be made by those skilled in the art without departing from the spirit and scope of the present invention, as defined by the appended claims and their equivalents. Throughout the description of the present invention, when describing a certain technology is determined to evade the point of the present invention, the pertinent detailed description will be omitted.

The terms used in the description are intended to describe certain embodiments only, and shall by no means restrict the present invention. Unless clearly used otherwise, expressions in the singular number include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof.

The wafer level LED interposer and its manufacturing method according to certain embodiments of the invention will be described below in more detail with reference to the accompanying drawings, in which those components are rendered the same reference number that are the same or are in correspondence, regardless of the figure number, and redundant explanations are omitted.

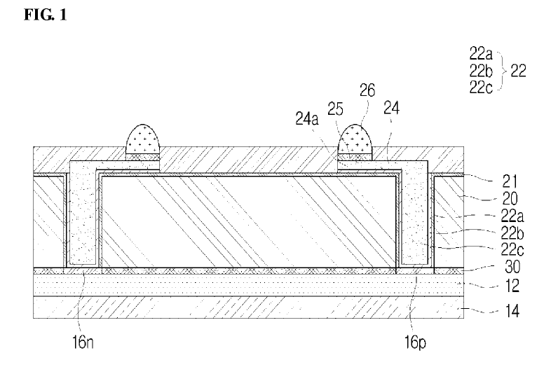

FIG. 1 is a sectional view illustrating a wafer level LED interposer according to an embodiment of the present invention. As shown in FIG. 1, a wafer level LED interposer according to an embodiment of the present invention comprises a LED chip 12 of which a n-type electrode 16n and a p-type electrode 16p are formed on the upper side; an interposer substrate 20 formed with through vias 22 at each position corresponding to the n-type electrode 16n and the p-type electrode 16p and bonded to the upper side of the LED chip 12; a redistribution layer 24 formed on the upper surface of the interposer substrate 20 and electrically connected to the through vias 22; a solder resist layer 28 coated on the upper surface of the interposer substrate 20 for a part of the redistribution layer 24a selectively to be opened; and an external connector 26 formed at the position where the redistribution layer 24 is opened. Here, the n-type electrode 16n and the p-type electrode 16p are connected to each through via 22.

The LED chip 12 may include a n-type and p-type semiconductor layer of a nitrogenous compound (not shown) and a nitride semiconductor structure such as an active layer (not shown) formed therebetween. When power is supplied to the LED chip 12 having this structure, the current flows between the p-type electrode 16p and the n-type electrode 16n and accordingly, light is emitted from the active layer (not shown). Here, the active layer is a region where electrons and holes combine and includes a quantum well layer and a quantum barrier layer which is represented by InₓGa₁₋ₓN (0≦x≦1). Emission wavelength emitted from the LED chip 12 is determined according to the type of materials forming the active layer.

Here, a fluorescent material layer (not shown) and a molding lens (not shown) may be formed on the bottom surface of the LED chip 12. As described above, since the LED chip 12 emits only a single light due to its characteristics, a color of light emitted from the LED chip 12 can be changed by coating a fluorescent material layer having a predetermined optical property on the surface thereof.

In addition, when a molding lens is formed by using a polymer and the like, a direction of light emitted from the LED chip 12 can be controlled to increase optical efficiency by improving the light intensity.

In addition, as shown in FIG. 1, a substrate 14 may be formed at the bottom part of the LED chip 12. The substrate 14 formed at the bottom part of the LED chip 12 may function as a substrate to grow a n-type semiconductor layer, an active layer, a p-type semiconductor layer and the like in order and be formed of a material such as sapphire, zinc oxide (ZnO), gallium Nitride (GaN), silicon carbide (SiC), aluminum nitride (AlN) and the like. The substrate 14 may be removed later by a laser lift-off process.

The interposer substrate 20 is bonded on the upper side of the LED chip 12, more particularly, on the surface where the n-type electrode 16n and the p-type electrode 16p are formed. Through vias 22 passing through the interposer substrate 20 are formed at each position corresponding to the n-type electrode 16n and the p-type electrode 16p. The n-type electrode 16n and the p-type electrode 16p are electrically connected to each through via 22 so that it is able to be electrically connected to a redistribution layer 24 formed on the upper surface of the interposer substrate 20.

The interposer substrate 20 may be glass or silicon. Hereinafter, embodiments of the present invention will be described with cases of that the interposer substrate 20 is formed with a silicon wafer.

A bonding layer 30 including an adhesive component may be formed between the LED chip 12 and the interposer substrate 20 to facilitate bonding between the LED chip 12 and the interposer substrate 20. The adhesive component included in the bonding layer 30 may be a thermosetting material, for example a polymer material such as epoxy and polyimide, etc., an inorganic material such as glass frit, a metallic material or the like.

The redistribution layer 24 may be formed on the upper surface of the interposer substrate 20 and electrically connected to the through vias 22 passing through the interposer substrate 20. The redistribution layer 24 may be used to change a channel of the through vias 22 to position an external connector at a position where a designer wants.

A part of the redistribution layer 24a can function as a connect pad where the external connector 26 is formed. Here, the rest part may be covered by a solder resist layer 28. That is, the solder resist layer 28 may be coated on the surface of the interposer substrate 20 to selectively expose only a part of the redistribution layer 24a.

In addition, a surface treated layer 25 such as a nickel/gold plated layer may be formed on a part of the redistribution layer 24a functioning as a connect pad.

The external connector 26 is formed on a part of the redistribution layer 24a, namely on the connect pad. For example, the external connector 26 may be a solder ball attached to the connect pad. Here, the solder ball is electrically connected to a printed circuit substrate (not shown). Besides the solder ball, a metal bump such as Cu, Au and Ni, etc. may be used as the external connector 26.

The above-described configuration is performed at a wafer level. Namely, it is performed on one wafer before sawing to separate a wafer composing the interposer substrate 20 into an individual unit. There are advantages in processing in a wafer unit and modularization by separating chips depending on user's needs.

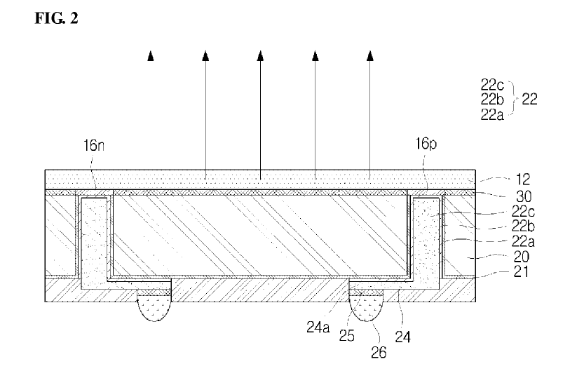

FIG. 2 illustrates light emitting from a wafer level LED interposer according to an embodiment of the present invention. FIG. 2 is a vertically flipped view of FIG. 1 in which a substrate 14 formed of a material such as sapphire is removed.

As shown in FIG. 2, a wafer level LED interposer according to an embodiment of the present invention emits light through the back surface of the LED chip 12, not a front surface of the LED chip on which the n-type electrode 16n and the p-type electrode 16p are formed. This back-lighting structure emits light from the LED chip 12 to the outside without being affected by the n-type electrode 16n and the p-type electrode 16p, and the redistribution layer 24, etc.

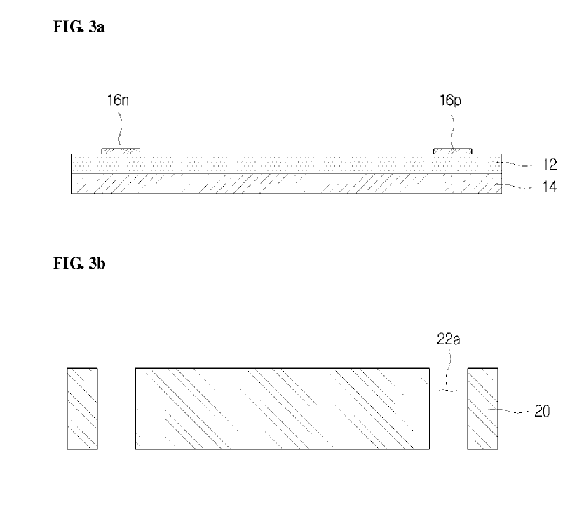

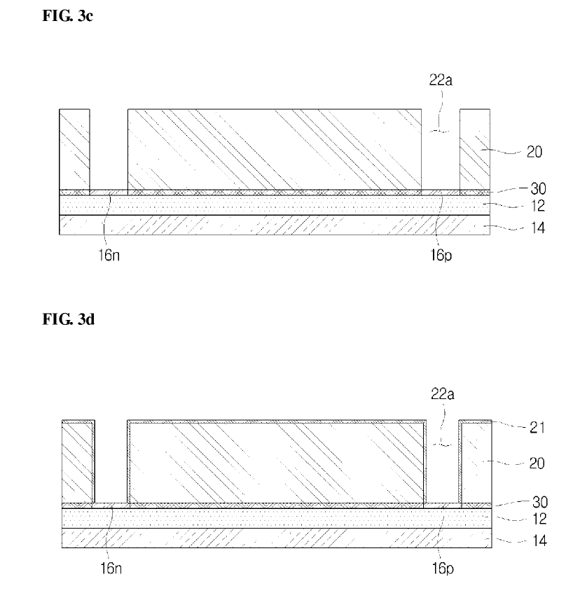

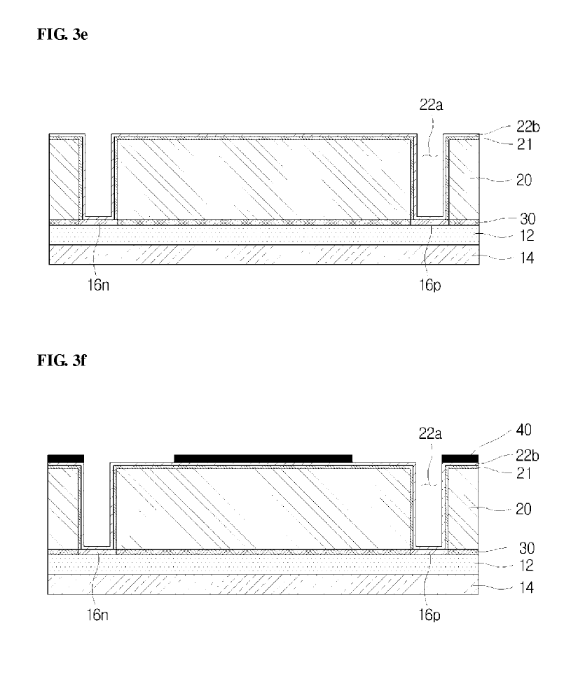

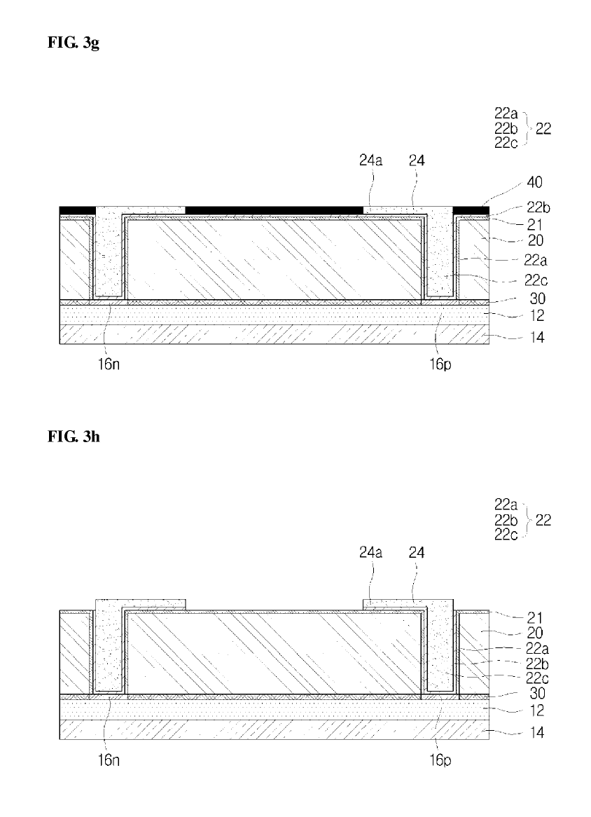

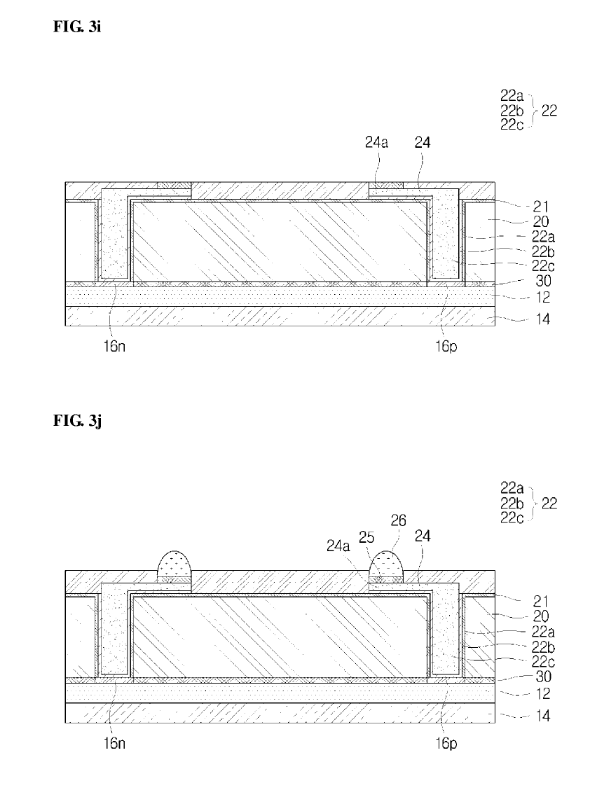

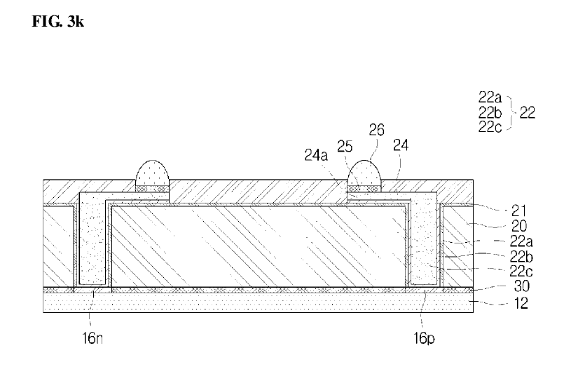

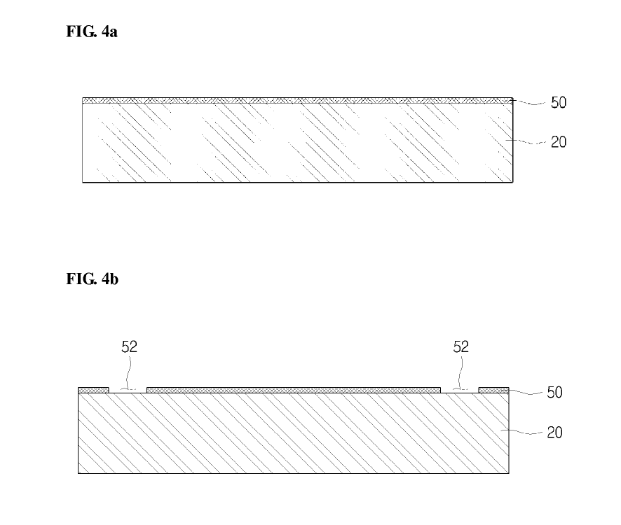

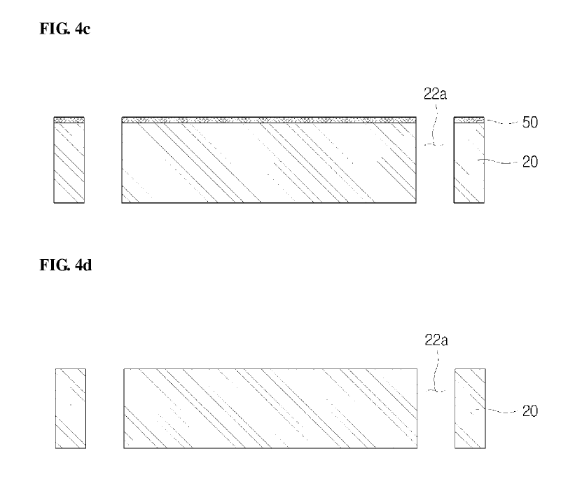

The structure of a wafer level LED interposer according to an aspect of the present invention has been described above and its manufacturing method will be described hereinafter. FIG. 3a to FIG. 3k illustrate each process for manufacturing a wafer level LED interposer according to an embodiment of the present invention. FIG. 4a to FIG. 4d illustrate a method for forming through holes 22a on an interposer substrate.

First, a LED chip 12 on which of an n-type electrode 16n and a p-type electrode 16p are formed is provided (FIG. 3a). The LED chip 12 may have a structure in which an n-type and a p-type semiconductor layer and a nitrogenous semiconductor compound such as an active layer positioned between the n-type and the p-type semiconductor layer are laminated on a substrate 14 such as sapphire. More particular description has been described above.

Apart from this, an interposer substrate 20 formed with through holes 22a at each position corresponding to the n-type electrode 16n and the p-type electrode 16p is provided (FIG. 3b). Here, the interposer substrate 20 may be a glass or silicon wafer as described above.

The through holes 22a passing through the interposer substrate 20 may be formed by using a drilling method such as laser drilling or mechanical drilling, etc., or an etching method such as dry etching using plasma or reactive ion etching, etc.

For example, when the etching method is used to from the through holes 22a, as shown in FIG. 4a to FIG. 4d, a photoresist 50 is coated on one surface of the interposer substrate 20. The photoresist 50 may be coated by a spin coating or a spray coating.

Patterns 52 may be formed on the photoresist 50 by using a photo mask and exposure and developing treatment. The through holes 22a may be formed by etching process at the regions where the patterns 52 are and which are corresponding to the p-type electrode 16p and the n-type electrode 16n. Then the photoresist 50 on the interposer substrate 20 may be removed.

The interposer substrate 20 is bonded on the upper side of the LED chip 12(FIG. 3c). Here, a bonding layer 30 including an adhesive component may be formed between the LED chip 12 and the interposer substrate 20 to facilitate bonding between the LED chip 12 and the interposer substrate 20. The adhesive component included in the bonding layer 30 may be a thermosetting material, for example a polymer material such as epoxy, and polyimide, etc., an inorganic material such as glass frit, a metallic material or the like.

Here, the n-type electrode 16n and the p-type electrode 16p are not covered by the bonding layer 30 but exposed to each through hole 22a formed on the interposer substrate 20.

Then, a conductive material is filled inside the through holes 22a to form through vias 22. A redistribution layer 24 which is electrically connected to the through vias 22 is formed on the upper surface of the interposer substrate 20. This will be described in more detail hereinafter.

As shown in FIG. 3d, an insulating thin film 21 is formed on the surface of the interposer substrate 20 and the inner surface of the through holes 22a to ensure the insulating property of the interposer substrate 20. For example, when the interposer substrate 20 is a glass wafer, the insulating thin film 21 can be formed on the surface of the glass wafer and the inner surface of the through holes 22a by using a spin coating or screen printing method.

When the interposer substrate 20 is a silicon wafer, the insulating thin film 21 can be formed on the surface of the silicon wafer and the inner surface of the through holes 22a by using a chemical vapor deposition (CVD) method. Here, the chemical vapor deposition (CVD) is a process which is used the most frequently among commercially available silicon thin film manufacturing technologies and which reduces density of by-products produced from air in the atmosphere by making inside the chamber, where the deposition occurs, be vacuum state and facilitates deposition rate.

As shown in FIG. 3e, a seed layer 22b is then formed on the exposed n-type electrode 16n and the p-type electrode 16p and the insulating thin film 21. Here, the seed layer 22b may be formed by an electroless plating method.

As shown in FIG. 3f, photoresist patterns 40 defining a redistribution layer 24 are formed on the seed layer 22b.

As shown in FIG. 3g, a conductive material 22c is filled inside the through holes 22a through a electro plating process using the seed layer 22b and the redistribution layer 24 defined by the photoresist patterns 40 is formed on the seed layer 22b. Here, the n-type electrode 16n and the p-type electrode 16p are connected to the conductive material 22c filled inside the through holes 22a.

The conductive material 22c, filled inside the through holes 22a and forming the redistribution layer 24, may be a material chosen from Cr, Cu, Ni, Au, Ag, Al, W, Ti, Pb, Zr, indium tin oxide (ITO) and a mixture thereof, preferably a material including at least one chosen from Cr, Cu and Ni.

As shown in FIG. 3h, the photoresist patterns 40 is removed by using a plasma etching and a part of the seed layer 22b exposed on the interposer substrate 20 is removed by a flash etching.

As described above, according to embodiments of the present invention, the through vias 22 and the redistribution layer 24 can be formed at the same process through the electroless plating and electro plating method, so that manufacturing time and cost can be reduced. However, the process of forming the through vias 22 and that of forming the redistribution layer 24 can be performed independently but it is not limited thereto.

A solder resist layer 28 is coated on the upper surface of the interposer substrate 20 to selectively open a part of the redistribution layer 24a (FIG. 3i). Here, the solder resist layer 28 may be formed with a polymer such as polyimide. The solder resist layer 28 may not only have insulation function but also act as stress buffer or movable layer to improve bonding properties of the interposer substrate 20 and the external connector 26 such as a solder ball.

The opened part of the redistribution layer 24a is a part to act as a connect pad later to form the external connector 26 thereon. A surface treated layer 25, for example a nickel/gold plated layer, may be formed on the connect pad 24a.

The external connector 26 is formed on the opened part of the redistribution layer 24 (FIG. 3j). The external connector 26 may be a solder ball or a metal bump such as Cu, Au or Ni, etc.

As shown in FIG. 3k, a substrate 14 is removed. The substrate 14 may be removed by a laser lift-off process as described above.

Then, a fluorescent material layer (not shown) may be coated on the bottom surface of the LED chip 12 and a molding lens (not shown) may be formed thereon to cover the fluorescent material layer.

Such processes are performed at a wafer level. Namely, each process described above is performed on one wafer before sawing to separate a wafer composing the interposer substrate 20 into an individual unit. There are advantages in processing in a wafer unit and manufacturing time and cost by separating units depending on user's needs.

While it has been described with reference to particular embodiments, it is to be appreciated that various changes and modifications may be made by those skilled in the art without departing from the spirit and scope of the embodiment herein, as defined by the appended claims and their equivalents.

As such, many embodiments other than that set forth above can be found in the appended claims.

DESCRIPTION OF REFERENCE NUMBERALS

| | |
|---|---|
| 12: LED chip | 14: substrate |
| 16n: N-type electrode | 16p: p-type electrode |
| 20: interposer substrate | 22: through vias |
| 24: redistribution layer | 26: external connector |
| 30: bonding layer | |

What is claimed is:

1. A wafer level LED interposer comprising:
a LED chip of which an n-type electrode and a p-type electrode are formed on the upper side;
an interposer substrate formed with through vias at each position corresponding to the n-type electrode and the p-type electrode and bonded to the upper side of the LED chip, wherein the n-type electrode and the p-type electrode are connected to each through via;
a redistribution layer formed on the upper surface of the interposer substrate and electrically connected to the through vias;
a solder resist layer coated on the upper surface of the interposer substrate for a part of the redistribution layer selectively to be opened; and
an external connector formed at the position where the redistribution layer is opened.

2. The wafer level LED interposer of claim 1, wherein the interposer substrate is glass or silicon.

3. The wafer level LED interposer of claim 1, wherein the redistribution layer is formed of a conductive material comprising at least one selected from the group consisting of Cr, Cu and Ni.

4. The wafer level LED interposer of claim 1, wherein the external connector comprises a solder ball attached to the position where the redistribution layer is opened.

5. The wafer level LED interposer of claim 1, further comprising a bonding layer formed between the LED chip and the interposer substrate and bonding the LED chip and the interposer substrate.

6. The wafer level LED interposer of claim 1, wherein the LED chip comprises a sapphire substrate; and a nitride semiconductor structure laminated on the sapphire substrate in which the nitride semiconductor structure comprises a p- and n-type semiconductor layer of a nitrogenous compound.

7. The wafer level LED interposer of claim 1, further comprising:
a fluorescent material layer formed on the bottom surface of the LED chip; and
a molding lens formed thereon to cover the fluorescent material layer.

8. A method for manufacturing a wafer level LED interposer comprising:
forming a LED chip of which an n-type electrode and a p-type electrode are formed on the upper side;
bonding an interposer substrate formed with through holes at each position corresponding to the n-type electrode and the p-type electrode to the upper side of the LED chip, wherein the n-type electrode and the p-type electrode are exposed by the through holes;
forming through vias by filling inside the each through hole with a conductive material, wherein the n-type electrode and the p-type electrode are connected to each through via;
forming a redistribution layer electrically connected to the through vias on the upper surface of the interposer substrate;
coating a solder resist layer on the upper surface of the interposer substrate for a part of the redistribution layer selectively to be opened; and
forming an external connector at the position where the redistribution layer is opened.

9. The method of claim 8, wherein the bonding step is performed by interposing a bonding layer between the LED chip and the interposer substrate.

10. The method of claim 8, wherein the step of forming through vias and the step of forming a redistribution layer are performed by the same process through electroless plating and electro plating method.

11. The method of claim 8, wherein the interposer substrate is glass or silicon.

12. The method of claim 8, wherein the LED chip comprises a sapphire substrate; and a nitride semiconductor structure laminated on the sapphire substrate in which the nitride semiconductor structure comprises a p- and n-type semiconductor layer of a nitrogenous compound.

13. The method of claim 1, further comprising:
coating a fluorescent material layer on the bottom surface of the LED chip; and
forming a molding lens on the bottom side of the LED chip to cover the fluorescent material layer.
